(19) United States
(12) Patent Application Publication
(10) Pub. No.: US 2024/0405723 A1
(43) Pub. Date: Dec. 5, 2024

(54) AMPLIFICATION SYSTEM, AMPLIFICATION MODULE, AND METHOD OF DRIVING AMPLIFICATION SYSTEM

(71) Applicant: Murata Manufacturing Co., Ltd., Nagaokakyo-shi (JP)

(72) Inventors: Yuuma NOGUCHI, Nagaokakyo-shi (JP); Kiichiro TAKENAKA, Nagaokakyo-shi (JP); Takeshi KOGURE, Nagaokakyo-shi (JP)

(21) Appl. No.: 18/800,331

(22) Filed: Aug. 12, 2024

Related U.S. Application Data
(63) Continuation of application No. PCT/JP2023/037523, filed on Oct. 17, 2023.

(30) Foreign Application Priority Data
Nov. 1, 2022 (JP) 2022-175826

(51) Int. Cl. H03F 1/02; H03F 3/04

(52) U.S. Cl. CPC H03F 1/0211; H03F 3/04; H03F 2200/105

(57) ABSTRACT

An amplification system configured to perform SPT and includes a DC/DC converter configured to output a power supply voltage Vcc1, a DC/DC converter configured to output a power supply voltage Vcc2, power amplifiers, and a switch configured to, in a first mode, selectively perform switching between a connection of the DC/DC converter and the power amplifier and a connection of the DC/DC converter and the power amplifier and, in a second mode, connect the DC/DC converter and the power amplifier and connect the DC/DC converter and the power amplifier.

### CROSS REFERENCE TO RELATED APPLICATIONS

This application is a continuation of International Application No. PCT/JP2023/037523, filed Oct. 17, 2023, which claims priority to Japanese Patent Application No. 2022-175826, filed Nov. 1, 2022, the entire contents of each of which are hereby incorporated in their entirety.

### TECHNICAL FIELD

The present disclosure is directed to an amplification system, an amplification module, and a method of driving the amplification system.

### BACKGROUND

U.S. Pat. No. 10,686,407 (the “'407 Patent”), discloses a symbol power tracking (SPT) amplification system for improving efficiency of an amplification circuit that amplifies a radio frequency signal having a wide band width. Specifically, the amplification system by the SPT is realized by alternately outputting a first voltage generated by a first DCDC converter and a second voltage generated by a second DCDC converter to the amplification circuit based on a trigger signal.

However, in the SPT amplification system disclosed in the '407 Patent, two voltage output circuits (DCDC converters) are required for one amplification circuit. Therefore, in a case where the SPT amplification system is applied to an amplification system having a plurality of amplification circuits, the circuit scale of the amplification system may be increased with an increase in the number of voltage output circuits.

### SUMMARY

The present disclosure can be widely used in communication devices such as mobile phones as an amplification system, an amplification module, and a method of driving an amplification system that are disposed at a multi-band compatible front-end portion.

Therefore, an aspect of the present disclosure is to provide a small-sized amplification system, an amplification module, and a method of driving an amplification system, each performing SPT.

Additionally, according to another aspect of the present disclosure, an amplification system performing SPT and includes a first voltage output circuit configured to output a first power supply voltage, a second voltage output circuit configured to output a second power supply voltage, a first amplification circuit, a second amplification circuit, and a first switch configured to, in a first mode, selectively perform switching between a connection of the first voltage output circuit and the first amplification circuit and a connection of the second voltage output circuit and the first amplification circuit and, in a second mode, connect the first voltage output circuit and the first amplification circuit and connect the second voltage output circuit and the second amplification circuit.

In addition, according to another aspect of the present disclosure, an amplification module performing SPT and includes a first power supply voltage terminal to which a first power supply voltage is applied and a second power supply voltage terminal to which a second power supply voltage is applied, a first amplification circuit, a second amplification circuit connected to the second power supply voltage terminal, and a first switch that includes a first common terminal, a first selection terminal, and a second selection terminal. The first common terminal is connected to the first amplification circuit, the first selection terminal is connected to the first power supply voltage terminal, and the second selection terminal is connected to the second power supply voltage terminal.

In addition, according to another aspect of the present disclosure, a method of driving an amplification system performing SPT and includes supplying a power supply voltage to the amplification system in a mode including a first mode and a second mode. In the first mode, a first power supply voltage and a second power supply voltage are selectively switched to cause a first amplification circuit to perform an amplification operation and cause a second amplification circuit not to perform an amplification operation. In the second mode, the first amplification circuit and the second amplification circuit are simultaneously caused to perform an amplification operation.

According to the present disclosure, it is possible to provide a small-sized amplification system, an amplification module, and a method of driving an amplification system, each performing SPT.

### BRIEF DESCRIPTION OF DRAWINGS

In the descriptions that follow, like parts are marked throughout the specification and drawings with the same numerals, respectively. The drawings are not necessarily drawn to scale and certain drawings may be shown in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1A is a graph showing an example of a transition of a power supply voltage in an average power tracking (APT) mode in accordance with aspects of the present disclosure;

FIG. 1B is a graph showing an example of a transition of the power supply voltage in an SPT mode in accordance with aspects of the present disclosure;

FIG. 1C is a graph showing an example of a transition of the power supply voltage in an analog envelope tracking (analog ET) mode in accordance with aspects of the present disclosure;

FIG. 2A is a diagram illustrating a frame, a subframe, a slot, and a symbol in accordance with aspects of the present disclosure;

FIG. 2B is a diagram illustrating a change in a level of the power supply voltage in the SPT mode in accordance with aspects of the present disclosure;

FIG. 3 is a circuit configuration diagram of an amplification system and a communication device in accordance with aspects of the present disclosure;

FIG. 4A is a diagram illustrating a circuit state of the amplification system in accordance with aspects of the present disclosure at time of a one-uplink operation;

FIG. 4B is a diagram illustrating a circuit state of the amplification system in accordance with aspects of the present disclosure at time of a two-uplink operation;

FIG. 5 is a flowchart illustrating a method of driving the amplification system in accordance with aspects of the present disclosure;

FIG. 6 is a circuit configuration diagram of an amplification system and a communication device in accordance with aspects of the present disclosure;

FIG. 7A is a diagram illustrating a first circuit state of the amplification system in accordance with aspects of the present disclosure at the time of a one-uplink operation;

FIG. 7B is a diagram illustrating a second circuit state of the amplification system in accordance with aspects of the present disclosure at the time of a one-uplink operation;

FIG. 7C is a diagram illustrating a circuit state of the amplification system in accordance with aspects of the present disclosure at the time of a two-uplink operation;

FIG. 8 is a circuit configuration diagram of an amplification system in accordance with aspects of the present disclosure;

FIG. 9 is a circuit configuration diagram of an amplification system in accordance with aspects of the present disclosure;

FIG. 10A is a diagram illustrating a circuit state of the amplification system in accordance with aspects of the present disclosure at the time of a one-uplink operation (wide channel band width);

FIG. 10B is a diagram illustrating a circuit state of the amplification system in accordance with aspects of the present disclosure at the time of a one-uplink operation (narrow channel band width);

FIG. 10C is a diagram illustrating a circuit state of the amplification system in accordance with aspects of the present disclosure at the time of a two-uplink operation; and

FIG. 11 is a flowchart illustrating a method of driving the amplification system in accordance with aspects of the present disclosure.

### DETAILED DESCRIPTION

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

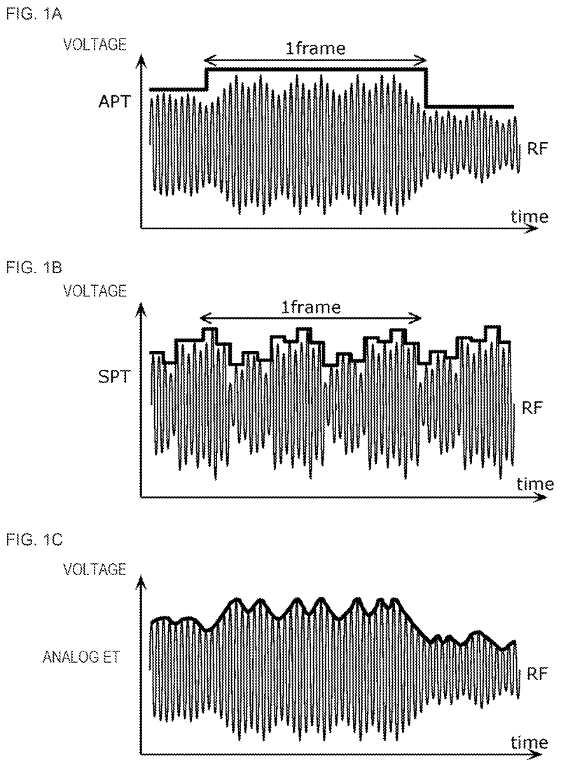

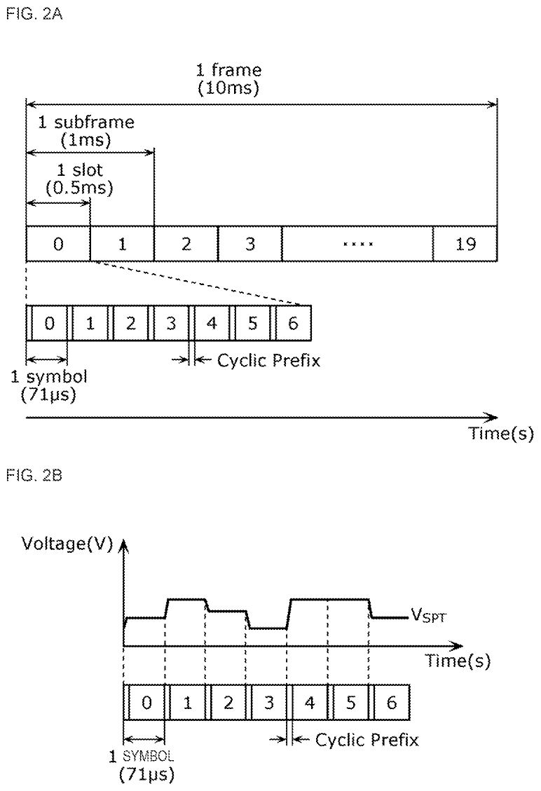

First, the SPT mode disclosed in the '407 Patent will be described with reference to FIGS. 1A to 2B in comparison with an APT mode and an analog ET mode.

FIG. 1A is a graph showing an example of a transition of a power supply voltage in the APT mode. FIG. 1B is a graph showing an example of a transition of the power supply voltage in the SPT mode. FIG. 1C is a graph showing an example of a transition of the power supply voltage in the analog ET mode. In FIGS. 1A to 1C, the horizontal axis represents time, and the vertical axis represents a voltage. In addition, a thick solid line represents the power supply voltage, and a thin solid line (waveform) represents a modulated signal.

In the APT mode of FIG. 1A, the level of the power supply voltage is modulated in units of one frame based on the average power in one frame section. That is, in the APT mode, the level of the power supply voltage can be changed in units of one frame. As a result, a plurality of discrete voltages are supplied to an amplification module over a plurality of frames.

In the APT mode, the level of the power supply voltage may be modulated in units smaller than one frame. For example, the level of the power supply voltage may be modulated in units of one subframe.

In the analog ET mode of FIG. 1C, an envelope of a radio frequency signal (modulated signal) is tracked by continuously changing the power supply voltage. In the analog ET mode, the power supply voltage is determined based on an envelope signal.

The envelope signal is a signal indicating the envelope of the modulated signal. An envelope value is represented by, for example, a square root of (I²+Q²). Here, (I, Q) represents a constellation point. The constellation point is a point representing a signal modulated by digital modulation on a constellation diagram. For example, (I, Q) is determined by a baseband integrated circuit (BBIC) based on transmission information.

In the SPT mode of FIG. 1B, the level of the power supply voltage is modulated in units of one symbol based on the power of a radio frequency signal in a symbol section. That is, in the SPT mode, the level of the power supply voltage can be changed in units of one symbol.

Here, the symbol will be described with reference to FIGS. 2A and 2B. FIG. 2A is a diagram illustrating a frame, a subframe, a slot, and a symbol. FIG. 2B is a diagram illustrating a change in the level of the power supply voltage in the SPT mode. FIGS. 2A and 2B illustrate relationships among a frame, a subframe, a slot, and a symbol in 5th Generation New Radio (5GNR) and a Long Term Evolution (LTE).

As illustrated in FIG. 2A, the frame is a unit of a radio frequency signal having a length of 10 milliseconds and includes, for example, 10 subframes. The subframe is a unit of a radio frequency signal having a length of 1 millisecond and includes, for example, two slots. The slot is a unit of a radio frequency signal having a length of 0.5 milliseconds and includes, for example, six symbols. The symbol is a unit of a radio frequency signal having a length of 71 microseconds and includes a cyclic prefix (CP).

As illustrated in FIG. 2B, in the SPT mode, the level of the power supply voltage is modulated in units of one symbol. At this time, the voltage level is changed in a section of the CP. For example, in the symbol “1”, the voltage level is changed to a higher level in the CP, and, in the symbol “2”, the voltage level is changed to a lower level in the CP. The voltage level does not need to be changed, as in the symbol “5”. The level of the power supply voltage can be modulated based on a data signal in each symbol section.

An aspect in which the APT mode, the analog ET mode, or the SPT mode described above is appropriately selected and the power supply voltage is supplied to the amplification module will be described in detail below with reference to the drawings.

The supply of the power supply voltage in the SPT mode is verified by operating a power supply circuit that outputs the power supply voltage and measuring a voltage waveform at a power supply input end of a power amplifier that receives the supply of the power supply voltage. At this time, in a case where the measured voltage is discretely changed in units smaller than one frame in the measurement at the power supply input end, it is determined that the power supply voltage is supplied in the SPT mode.

The aspects described below describe comprehensive or specific examples. Numerical values, shapes, materials, constituents, a disposition and a connection form of the constituents, and the like illustrated in the following aspects are examples and not intended to limit the present disclosure.

Each drawing is a schematic view in which emphasis, omission, or ratio adjustment is made as appropriate to represent the present disclosure, and is not necessarily illustrated strictly. In some cases, a shape, a positional relationship, and a ratio may be different from actual ones. In the drawings, the substantially same configurations are denoted by the same reference signs, and repeated description thereof may be omitted or simplified in some cases.

In the circuit configuration of the present disclosure, the expression “connected” means a case of being electrically connected through another circuit element in addition to a case of being directly connected by a connection terminal and/or a wiring conductor. The expression “being connected between A and B” means being connected to both A and B between A and B.

In the component disposition of the present disclosure, the expression “a component is disposed at a board” means that the component is disposed on the main surface of the board and that the component is disposed in the board.

In addition, terms representing a relationship between elements such as “parallel” and “perpendicular”, terms representing a shape of an element such as “rectangular”, and a numerical range not only represent strict meanings, but also include a substantially equivalent range such as an error of approximately several percent.

In addition, in the present disclosure, the term “terminal” means a point where a conductor in an element ends. In a case where the impedance of a path between elements is sufficiently low, the terminal is interpreted as not only a single point but also any point on the path between the elements or the entire path.

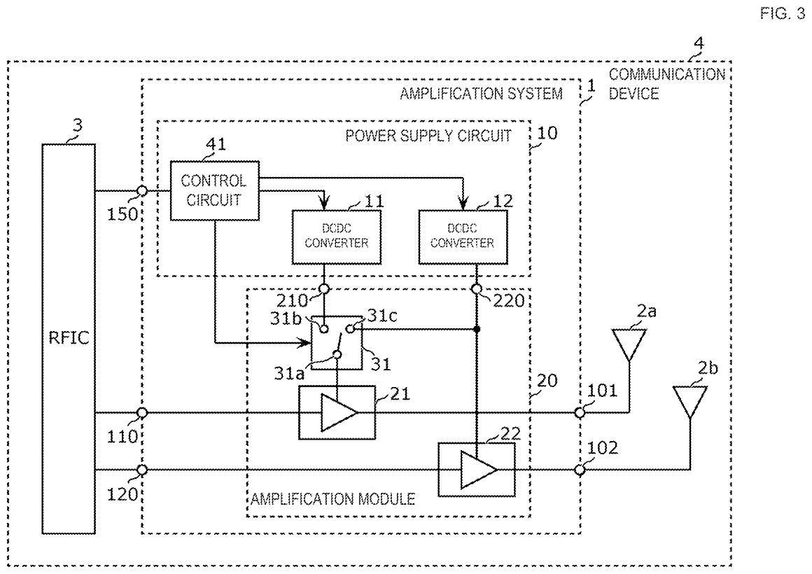

An amplification system 1 and a communication device 4 according to the present disclosure will be described with reference to FIG. 3.

FIG. 3 is a configuration diagram of the amplification system 1 and the communication device 4 according to an aspect of the present disclosure. The communication device 4 according to an aspect of the present disclosure corresponds to user equipment (UE) in a cellular network and is typically a mobile phone, a smartphone, a tablet computer, a wearable device, or the like. The communication device 4 may be an Internet of Things (IoT) sensor/device, a medical/healthcare device, a vehicle, an unmanned aerial vehicle (UAV) (so-called drone), or an automated guided vehicle (AGV).

First, the circuit configuration of the communication device 4 will be described. As illustrated in FIG. 3, the communication device 4 according to an aspect of the present disclosure includes the amplification system 1, antennas 2a and 2b, and a radio frequency integrated circuit (RFIC) 3.

The amplification system 1 includes a power supply circuit 10, an amplification module 20, antenna connection terminals 101 and 102, signal input terminals 110 and 120, and a control signal terminal 150.

The antennas 2a and 2b are connected to the amplification module 20 and transmit a radio frequency signal output from the amplification module 20.

The RFIC 3 is an example of a signal processing circuit that processes the radio frequency signal. Specifically, the RFIC 3 performs signal processing on a transmission signal input from a BBIC (not illustrated) by up-conversion or the like and outputs a radio frequency transmission signal generated by the signal processing to the amplification module 20. In addition, the RFIC 3 includes a control unit that controls a switch, a power amplifier, and the like provided in the amplification module 20 and/or the power supply circuit 10. Some or all of the functions as the control unit of the RFIC 3 may be configured outside the RFIC 3 and, for example, may be configured in the BBIC, the amplification module 20, or the power supply circuit 10.

The power supply circuit 10 includes DCDC converters 11 and 12 and a control circuit 41.

The control circuit 41 can control the DCDC converters 11 and 12 and a switch 31 of the amplification module 20. For example, in a case where the power supply voltage in the SPT mode is supplied to the amplification module 20, the control circuit 41 can receive a digital control signal from the RFIC 3, provide a first voltage level control signal and a second voltage level control signal indicating the voltage level of the symbol to the DCDC converters 11 and 12, respectively, and provide a switching control signal to the switch 31. In addition, for example, in a case where the power supply voltage in the APT mode is supplied to the amplification module 20, the control circuit 41 can receive a control signal corresponding to the average power in one frame section from the RFIC 3, provide the first voltage level control signal and the second voltage level control signal corresponding to the average power to the DCDC converters 11 and 12, respectively, and provide the switching control signal to the switch 31.

The DCDC converter 11 is an example of a first voltage output circuit and is configured to output a power supply voltage Vcc1 (first power supply voltage). The DCDC converter 11 has, for example, one power inductor and outputs a DC power supply voltage Vcc1. The DCDC converter 11 can change the level of the power supply voltage Vcc1 for each symbol corresponding to the DCDC converter 11 or for each average power, based on the first voltage level control signal received from the control circuit 41.

The DCDC converter 12 is an example of a second voltage output circuit and is configured to output a power supply voltage Vcc2 (second power supply voltage). The DCDC converter 12 has, for example, one power inductor and outputs a DC power supply voltage Vcc2. The DCDC converter 12 can change the level of the power supply voltage Vcc2 for each symbol corresponding to the DCDC converter 12 or for each average power, based on the second voltage level control signal received from the control circuit 41.

The amplification module 20 receives a supply of a variable power supply voltage in the SPT mode, the APT mode, or the like from the power supply circuit 10, amplifies the radio frequency signal input from the RFIC 3, and outputs the amplified radio frequency signal to the antennas 2a and 2b. The amplification module 20 includes power amplifiers 21 and 22, the switch 31, and power supply voltage terminals 210 and 220.

The power supply voltage terminal 210 is an example of a first power supply voltage terminal. The power supply voltage terminal 210 is connected to the switch 31 and the DCDC converter 11, and the power supply voltage Vcc1 is applied thereto. The power supply voltage terminal 220 is an example of a second power supply voltage terminal. The power supply voltage terminal 220 is connected to the switch 31, the power amplifier 22, and the DCDC converter 12, and the power supply voltage Vcc2 is applied thereto.

The power amplifier 21 is an example of a first amplification circuit, in which a signal input end is connected to the signal input terminal 110, a signal output end is connected to the antenna connection terminal 101, and a power supply input end is connected to the power supply voltage terminals 210 and 220 through the switch 31. The power amplifier 21 receives the supply of the power supply voltage from the power supply circuit 10, amplifies, for example, a radio frequency signal having a band A, which is input from the signal input terminal 110, and outputs the amplified radio frequency signal to the antenna connection terminal 101.

The power amplifier 22 is an example of a second amplification circuit, in which a signal input end is connected to the signal input terminal 120, a signal output end is connected to the antenna connection terminal 102, and a power supply input end is connected to the power supply voltage terminal 220. The power amplifier 22 receives the supply of the power supply voltage from the power supply circuit 10, amplifies, for example, a radio frequency signal having a band B, which is input from the signal input terminal 120, and outputs the amplified radio frequency signal to the antenna connection terminal 102.

The switch 31 is an example of a first switch and includes a common terminal 31a (first common terminal), a selection terminal 31b (first selection terminal), and a selection terminal 31c (second selection terminal). The switch 31 selectively (exclusively) performs switching between a connection of the common terminal 31a and the selection terminal 31b and a connection of the common terminal 31a and the selection terminal 31c. The common terminal 31a is connected to the power supply input end of the power amplifier 21. The selection terminal 31b is connected to the DCDC converter 11 through the power supply voltage terminal 210. The selection terminal 31c is connected to the DCDC converter 12 through the power supply voltage terminal 220.

According to such a connection configuration, in the first mode, the switch 31 selectively performs switching between a connection of the DCDC converter 11 and the power amplifier 21 and a connection of the DCDC converter 12 and the power amplifier 21. In addition, in the second mode, the switch 31 connects the DCDC converter 11 and the power amplifier 21 and disconnects the DCDC converter 12 and the power amplifier 21.

As a result, for example, the first mode is applied to the SPT mode, and the switch 31 can alternately select the DCDC converters 11 and 12 for each symbol based on the switching control signal output from the control circuit 41 and connect the selected DCDC converter to the power amplifier 21. As a result, the switch 31 can supply a power supply voltage V_{SPT} modulated by the SPT mode to the power amplifier 21.

In addition, for example, the second mode is applied to the APT mode, and the switch 31 can connect only to or alternatively the DCDC converter 11 to the power amplifier 21 without connecting the DCDC converter 12 to the power amplifier 21, based on the switching control signal output from the control circuit 41. As a result, the switch 31 can supply a power supply voltage V_{APT} modulated by the APT mode to the power amplifier 21. In addition, at this time, the DCDC converter 12 can supply, the power supply voltage V_{APT} modulated by the APT mode to the power amplifier 22.

The amplification module 20 may further include a module laminate. In this case, the power amplifiers 21 and 22, the switch 31, and the power supply voltage terminals 210 and 220 are disposed at the module laminate. In addition, the power supply voltage terminals 210 and 220 are external connection terminals exposed to an outer surface of the amplification module 20.

The switch 31 may have a configuration of performing switching between the connection and the disconnection of the DCDC converter 12 and the power amplifier 22.

Next, a circuit operation of the amplification system 1 will be described.

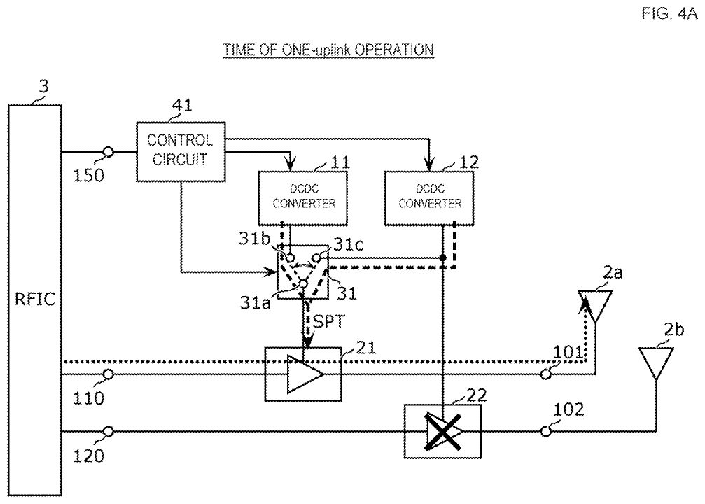

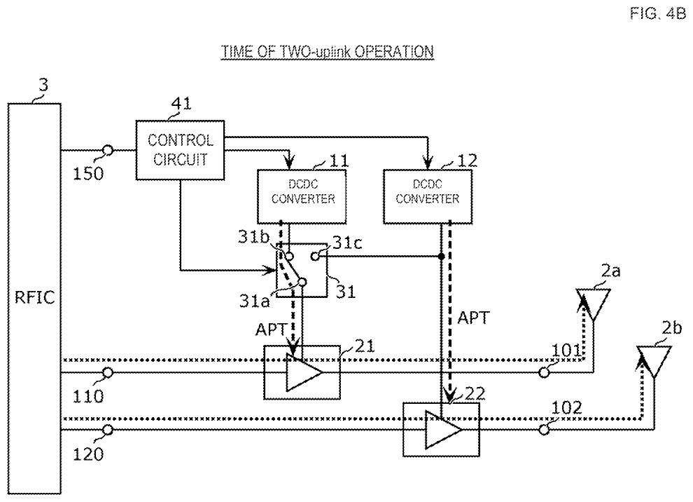

FIG. 4A is a diagram illustrating a circuit state of the amplification system 1 according to an aspect of the present disclosure at time of a one-uplink operation. FIG. 4A illustrates a circuit state in a case where the power amplifier 21 performs an amplification operation and the power amplifier 22 does not perform an amplification operation, and the first mode is performed. In this case, for example, a radio frequency transmission signal having a band A is output from the antenna 2a, and a radio frequency transmission signal having a band B is not output from the antenna 2b. At this time, the connection of the common terminal 31a and the selection terminal 31b and the connection of the common terminal 31a and the selection terminal 31c are selectively switched. The power supply voltages Vcc1 and Vcc2 are alternately supplied from the DCDC converters 11 and 12 to the power amplifier 21 for each symbol, and the power amplifier 21 performs an amplification operation in the SPT mode.

The state in which the power amplifier does not perform the amplification operation is realized by not inputting the radio frequency signal to the signal input end of this power amplifier and/or not supplying a bias current (bias voltage) to this power amplifier.

FIG. 4B is a diagram illustrating a circuit state of the amplification system 1 according to an aspect of the present disclosure at time of a two-uplink operation. FIG. 4B illustrates a circuit state in a case where both the power amplifiers 21 and 22 perform the amplification operation, and the second mode is performed. In this case, for example, the radio frequency transmission signal having the band A is output from the antenna 2a, and the radio frequency transmission signal having the band B is output from the antenna 2b. At this time, the common terminal 31a and the selection terminal 31b are connected, and the common terminal 31a and the selection terminal 31c are disconnected. The power supply voltage Vcc1 corresponding to the average power is supplied to the power amplifier 21, the power supply voltage Vcc2 corresponding to the average power is supplied to the power amplifier 22, and the power amplifiers 21 and 22 perform the amplification operation in the APT mode.

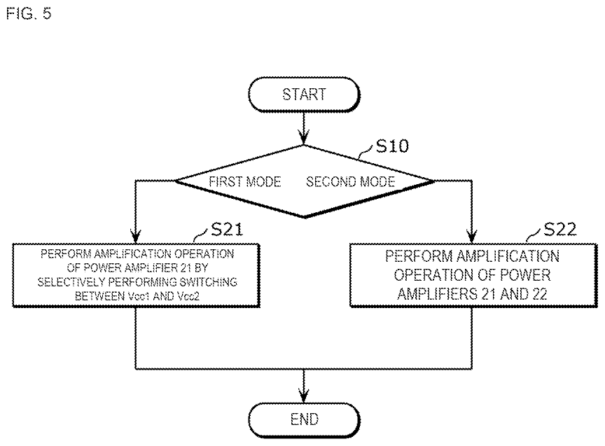

FIG. 5 is a flowchart illustrating a method of driving the amplification system 1 according to an aspect of the present disclosure. As illustrated in FIG. 5, a mode of supplying the power supply voltage to the amplification system 1 includes a first mode and a second mode (S10).

In the first mode, the power supply voltages Vcc1 and Vcc2 are selectively switched, and the power supply voltage is supplied to the power amplifier 21 to cause the power amplifier 21 to perform an amplification operation (S21). In this case, the power amplifier 22 does not perform an amplification operation.

In the second mode, the power supply voltage Vcc1 is supplied to the power amplifier 21 to cause the power amplifier 21 to perform an amplification operation, and, simultaneously, the power supply voltage Vcc2 is supplied to the power amplifier 22 to cause the power amplifier 22 to perform an amplification operation (S22).

That is, in a case where the power amplifier 21 is caused to perform the amplification operation and the power amplifier 22 is not caused to perform the amplification operation (in a case of a one-uplink operation), the first mode is performed. In addition, in a case where the power amplifiers 21 and 22 are simultaneously caused to perform the amplification operation (in a case of a two-uplink operation), the second mode is performed.

The two-uplink operation includes (1) simultaneous transmission (carrier aggregation) of a first radio frequency signal of LTE and a second radio frequency signal of LTE, (2) simultaneous transmission (carrier aggregation) of a first radio frequency signal of 5G-NR and a second radio frequency signal of 5G-NR, and (3) simultaneous transmission (dual connectivity) of a first radio frequency signal of LTE and a second radio frequency signal of 5G-NR.

In the present disclosure, the first mode is the SPT mode, and the second mode is the APT mode.

The power amplifier 21 configured to amplify a radio frequency signal of an ultra-high band group, and the power amplifier 22 configured to amplify radio frequency signals of a low band group and a middle-high band group.

According to this, the power amplifier 21 performing the SPT mode can be caused to perform the amplification operation on the radio frequency signal of the ultra-high band group that has a relatively wide channel band width, and the power amplifier 22 performing the APT mode can be caused to perform the amplification operation on the radio frequency signals of the low band group and the middle-high band group which have a relatively narrow channel band width. Therefore, it is possible to reduce the deterioration in the efficiency of the amplification system 1.

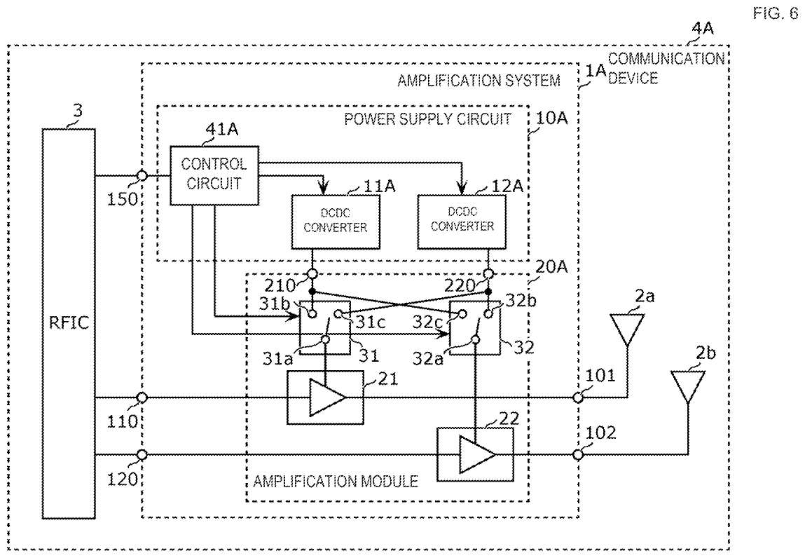

Next, an amplification system 1A and a communication device 4A according to an aspect of the present disclosure will be described with reference to FIG. 6.

FIG. 6 is a circuit configuration diagram of the amplification system 1A and the communication device 4A according to an aspect of the present disclosure. As illustrated in FIG. 6, the communication device 4A according to an aspect of the present disclosure includes the amplification system 1A, antennas 2a and 2b, and an RFIC 3. The communication device 4A is different from the communication device 4 according to the aspect only in the configuration of the amplification system 1A. Therefore, the circuit configuration of the amplification system 1A will be mainly described below.

The amplification system 1A includes a power supply circuit 10A, an amplification module 20A, antenna connection terminals 101 and 102, signal input terminals 110 and 120, and a control signal terminal 150. The amplification system 1A according to an aspect of the present disclosure is different from the amplification system 1 according to the aspect in that a switch 32 is added. The amplification system 1A will be described below mainly focusing on different configurations without describing the same configurations as the amplification system 1.

The power supply circuit 10A includes DCDC converters 11A and 12A and a control circuit 41A.

The control circuit 41A can control the DCDC converters 11A and 12A and switches 31 and 32 of the amplification module 20A. For example, in a case where the power supply voltage in the SPT mode is supplied to the amplification module 20A, the control circuit 41A can receive a digital control signal from the RFIC 3, provide a first voltage level control signal and a second voltage level control signal indicating the voltage level of the symbol to the DCDC converters 11A and 12A, respectively, and provide a switching control signal to the switch 31 or 32. In addition, for example, in a case where the power supply voltage in the APT mode is supplied to the amplification module 20A, the control circuit 41A can receive a control signal corresponding to the average power in one frame section from the RFIC 3, provide the first voltage level control signal and the second voltage level control signal corresponding to the average power to the DCDC converters 11A and 12A, respectively, and provide the switching control signals to the switches 31 and 32.

The DCDC converter 11A is an example of the first voltage output circuit and is configured to output the power supply voltage Vcc1 (first power supply voltage) to the power supply voltage terminal 210. The DCDC converter 11A includes, for example, one power inductor and outputs the DC power supply voltage Vcc1. The DCDC converter 11A can change the level of the power supply voltage Vcc1 for each symbol corresponding to the DCDC converter 11A or for each average power, based on the first voltage level control signal received from the control circuit 41A.

The DCDC converter 12A is an example of the second voltage output circuit and is configured to output the power supply voltage Vcc2 (second power supply voltage) to the power supply voltage terminal 220. The DCDC converter 12A includes, for example, one power inductor and outputs the DC power supply voltage Vcc2. The DCDC converter 12A can change the level of the power supply voltage Vcc2 for each symbol corresponding to the DCDC converter 12A or for each average power, based on the second voltage level control signal received from the control circuit 41A.

The amplification module 20A receives a supply of a variable power supply voltage in the SPT mode, the APT mode, or the like from the power supply circuit 10A, amplifies the radio frequency signal input from the RFIC 3, and outputs the amplified radio frequency signal to the antennas 2a and 2b. The amplification module 20A includes power amplifiers 21 and 22, the switches 31 and 32, and power supply voltage terminals 210 and 220.

The power supply voltage terminal 210 is an example of the first power supply voltage terminal. The power supply voltage terminal 210 is connected to the switches 31 and 32, and the power supply voltage Vcc1 is applied thereto. The power supply voltage terminal 220 is an example of the second power supply voltage terminal. The power supply voltage terminal 220 is connected to the switches 32 and 31, and the power supply voltage Vcc2 is applied thereto.

The power amplifier 21 is an example of the first amplification circuit, in which a signal input end is connected to the signal input terminal 110, a signal output end is connected to the antenna connection terminal 101, and a power supply input end is connected to power supply voltage terminals 210 and 220 through the switch 31.

The power amplifier 22 is an example of the second amplification circuit, in which a signal input end is connected to the signal input terminal 120, a signal output end is connected to the antenna connection terminal 102, and a power supply input end is connected to power supply voltage terminals 210 and 220 through the switch 32.

The common terminal 31a of the switch 31 is connected to the power supply input end of the power amplifier 21. The selection terminal 31b is connected to the DCDC converter 11A through the power supply voltage terminal 210. The selection terminal 31c is connected to the DCDC converter 12A through the power supply voltage terminal 220.

The switch 32 is an example of a second switch, and includes a common terminal 32a (second common terminal), a selection terminal 32b (third selection terminal), and a selection terminal 32c (fourth selection terminal). The switch 32 selectively (exclusively) performs switching between a connection of the common terminal 32a and the selection terminal 32b and a connection of the common terminal 32a and the selection terminal 32c. The common terminal 32a is connected to the power supply input end of the power amplifier 22. The selection terminal 32b is connected to the DCDC converter 12A through the power supply voltage terminal 220. The selection terminal 32c is connected to the DCDC converter 11A through the power supply voltage terminal 210.

With such a connection configuration, in the first mode, the switch 31 selectively performs switching between a connection of the DCDC converter 11A and the power amplifier 21 and a connection of the DCDC converter 12A and the power amplifier 21. In addition, in the second mode, the switch 31 connects the DCDC converter 11A and the power amplifier 21 and disconnects the DCDC converter 12A and the power amplifier 21. In addition, in a fourth mode, the switch 32 selectively performs switching between a connection of the DCDC converter 11A and the power amplifier 22 and a connection of the DCDC converter 12A and the power amplifier 22. In addition, in the second mode, the switch 32 connects the DCDC converter 12A and the power amplifier 22 and disconnects the DCDC converter 11A and the power amplifier 22.

As a result, the first mode is applied to, for example, the SPT mode, and the switch 31 can alternately select the DCDC converters 11A and 12A for each symbol based on the switching control signal output from the control circuit 41A and connect the selected DCDC converter to the power amplifier 21. As a result, the switch 31 can supply a power supply voltage V_{SPT} modulated by the SPT mode to the power amplifier 21. In addition, the fourth mode is applied to, for example, the SPT mode, and the switch 32 can alternately select the DCDC converters 11A and 12A for each symbol based on the switching control signal output from the control circuit 41A and connect the selected DCDC converter to the power amplifier 22. As a result, the switch 32 can supply the power supply voltage V_{SPT} modulated by the SPT mode to the power amplifier 22.

In addition, the second mode is applied to, for example, the APT mode. The switch 31 can connect only the DCDC converter 11A to the power amplifier 21 without connecting the DCDC converter 12A to the power amplifier 21, based on the switching control signal output from the control circuit 41A. In addition, the switch 32 can connect only the DCDC converter 12A to the power amplifier 22 without connecting the DCDC converter 11A to the power amplifier 22, based on the switching control signal output from the control circuit 41A. As a result, the switch 31 can supply the power supply voltage V_{APT} modulated by the APT mode to the power amplifier 21, and, simultaneously, the switch 32 can supply the power supply voltage V_{APT} modulated by the APT mode to the power amplifier 22.

The amplification module 20A may further include a module laminate. In this case, the power amplifiers 21 and 22, the switches 31 and 32, and the power supply voltage terminals 210 and 220 are disposed at the module laminate. In addition, the power supply voltage terminals 210 and 220 are external connection terminals exposed to an outer surface of the amplification module 20A.

Next, a circuit operation of the amplification system 1A will be described.

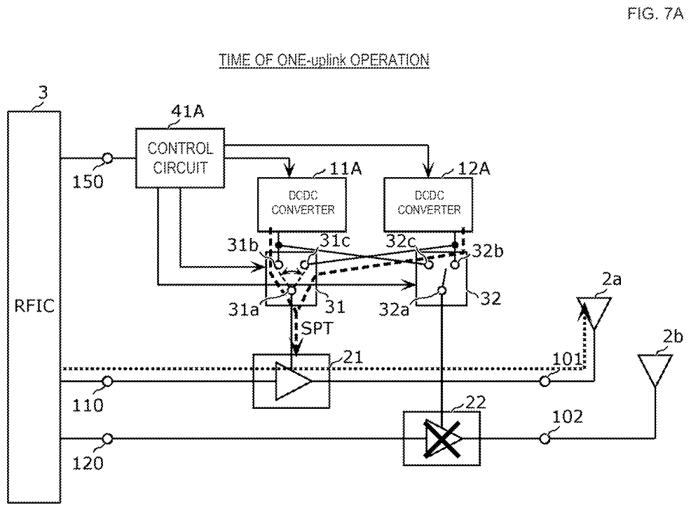

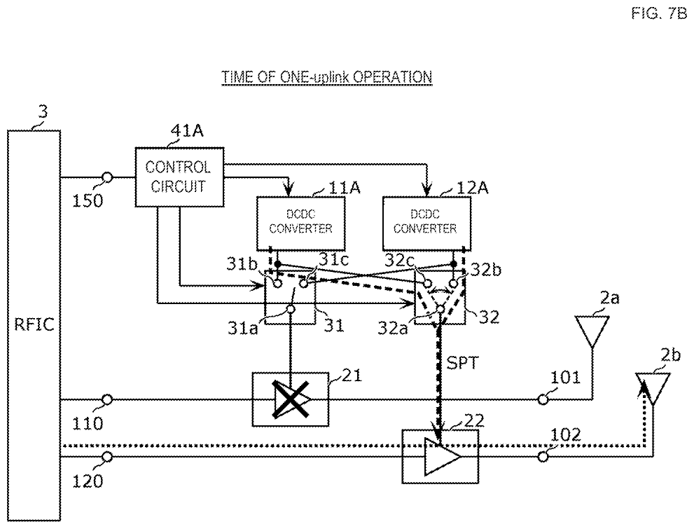

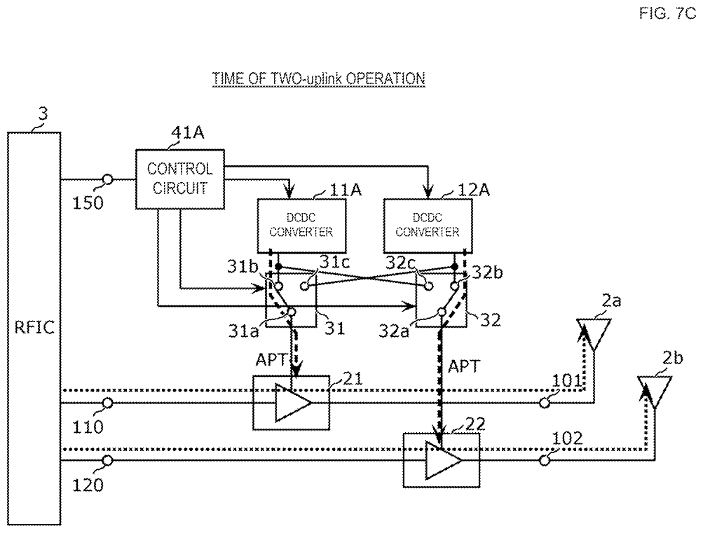

FIG. 7A is a diagram illustrating a first circuit state of the amplification system 1A according to an aspect of the present disclosure of the aspect at the time of a one-uplink operation. FIG. 7A illustrates a circuit state in a case where the power amplifier 21 performs an amplification operation and the power amplifier 22 does not perform an amplification operation, and the first mode is performed. In this case, for example, a radio frequency transmission signal having a band A is output from the antenna 2a, and a radio frequency transmission signal having a band B is not output from the antenna 2b. At this time, the connection of the common terminal 31a and the selection terminal 31b and the connection of the common terminal 31a and the selection terminal 31c are selectively switched. The power supply voltages Vcc1 and Vcc2 are alternately supplied from the DCDC converters 11A and 12A to the power amplifier 21 for each symbol, and the power amplifier 21 performs an amplification operation in the SPT mode.

FIG. 7B is a diagram illustrating a second circuit state of the amplification system 1A according to an aspect of the present disclosure of the aspect at the time of a one-uplink operation. FIG. 7B illustrates a circuit state in a case where the power amplifier 22 performs an amplification operation and the power amplifier 21 does not perform an amplification operation, and the fourth mode is performed. In this case, for example, the radio frequency transmission signal having the band B is output from the antenna 2b, and the radio frequency transmission signal having the band A is not output from the antenna 2a. At this time, the connection of the common terminal 32a and the selection terminal 32b and the connection of the common terminal 32a and the selection terminal 32c are selectively switched. The power supply voltages Vcc1 and Vcc2 are alternately supplied from the DCDC converters 11A and 12A to the power amplifier 22 for each symbol, and the power amplifier 22 performs an amplification operation in the SPT mode.

FIG. 7C is a diagram illustrating a circuit state of the amplification system 1A according to an aspect of the present disclosure of the aspect at the time of a two-uplink operation. FIG. 7C illustrates a circuit state in a case where both the power amplifiers 21 and 22 perform the amplification operation, and the second mode is performed. In this case, for example, the radio frequency transmission signal having the band A is output from the antenna 2a, and the radio frequency transmission signal having the band B is output from the antenna 2b. In this case, the common terminal 31a and the selection terminal 31b are connected, the common terminal 31a and the selection terminal 31c are disconnected, and the power supply voltage Vcc1 corresponding to the average power is supplied to the power amplifier 21. In addition, at the same time, the common terminal 32a and the selection terminal 32b are connected, the common terminal 32a and the selection terminal 32c are disconnected, and the power supply voltage Vcc2 corresponding to the average power is supplied to the power amplifier 22. That is, the power amplifiers 21 and 22 perform the amplification operation in the APT mode.

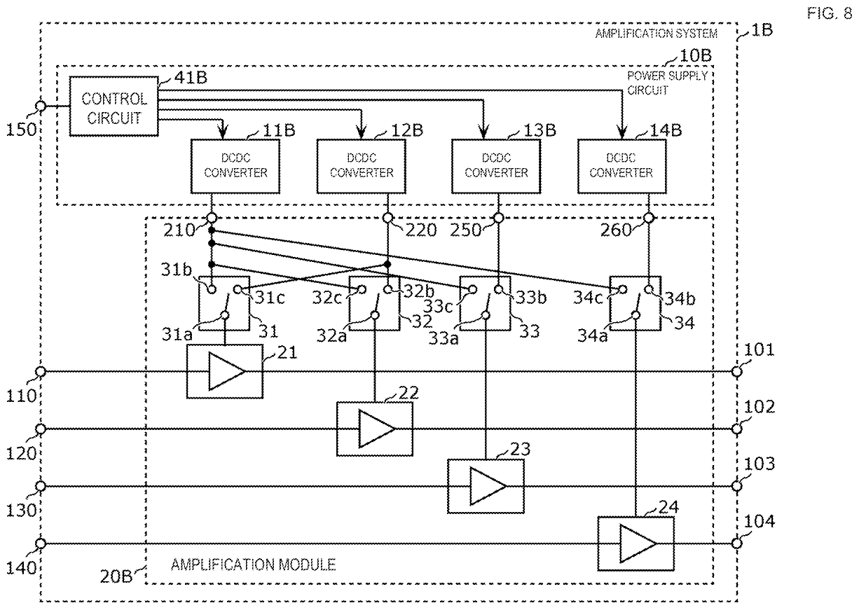

Next, an amplification system 1B according to an aspect of the present disclosure will be described with reference to FIG. 8.

FIG. 8 is a circuit configuration diagram of the amplification system 1B according to an aspect of the present disclosure. As illustrated in FIG. 8, the amplification system 1B according to an aspect of the present disclosure includes a power supply circuit 10B, an amplification module 20B, antenna connection terminals 101, 102, 103, and 104, signal input terminals 110, 120, 130, and 140, and a control signal terminal 150. The amplification system 1B according to an aspect of the present disclosure is different from the amplification system 1A according to an aspect of the present disclosure in that the number of power amplifiers, switches, and DCDC converters is increased. The amplification system 1B will be described below mainly focusing on different configurations without describing the same configurations as the amplification system 1A according to an aspect of the present disclosure.

The power supply circuit 10B includes DCDC converters 11B, 12B, 13B, and 14B, and a control circuit 41B.

The control circuit 41B can control the DCDC converters 11B to 14B and each switch of the amplification module 20B. For example, in a case where the power supply voltage in the SPT mode is supplied to a power amplifier 21 of the amplification module 20B, the control circuit 41B can receive a digital control signal from the RFIC 3, provide a first voltage level control signal and a second voltage level control signal indicating the voltage level of the symbol to the DCDC converters 11B and 12B, respectively, and provide a switching control signal to a switch 31. In addition, for example, in a case where the power supply voltage in the SPT mode is supplied to a power amplifier 22 of the amplification module 20B, the control circuit 41B can receive the digital control signal from the RFIC 3, provide the first voltage level control signal and the second voltage level control signal indicating the voltage level of the symbol to the DCDC converters 11B and 12B, respectively, and provide the switching control signal to a switch 32. In addition, for example, in a case where the power supply voltage in the SPT mode is supplied to a power amplifier 23 of the amplification module 20B, the control circuit 41B can receive the digital control signal from the RFIC 3, provide a first voltage level control signal and a third voltage level control signal indicating the voltage level of the symbol to the DCDC converters 11B and 13B, respectively, and provide the switching control signal to a switch 33. In addition, for example, in a case where the power supply voltage in the SPT mode is supplied to a power amplifier 24 of the amplification module 20B, the control circuit 41B can receive the digital control signal from the RFIC 3, provide the first voltage level control signal and a fourth voltage level control signal indicating the voltage level of the symbol to the DCDC converters 11B and 14B, respectively, and provide the switching control signal to a switch 34. In addition, for example, in a case where the power supply voltage in the APT mode is supplied to each power amplifier of the amplification module 20B, the control circuit 41B can receive the control signal corresponding to the average power in one frame section from the RFIC 3, provide the first voltage level control signal, the second voltage level control signal, the third voltage level control signal, and the fourth voltage level control signal corresponding to the average power to the DCDC converters 11B, 12B, 13B, and 14B, respectively, and provide the switching control signals to the switches 31, 32, 33, and 34, respectively.

The DCDC converter 11B is an example of the first voltage output circuit and is configured to output a DC power supply voltage Vcc1 (first power supply voltage). The DCDC converter 12B is an example of the second voltage output circuit and is configured to output a DC power supply voltage Vcc2 (second power supply voltage). The DCDC converter 13B is configured to output a DC power supply voltage Vcc3. The DCDC converter 14B is configured to output a DC power supply voltage Vcc4. Each of the DCDC converters 11B to 14B can change the level of the power supply voltages Vcc1 to Vcc4 for each symbol corresponding to the DCDC converter 11B to 14B or for each average power, based on the voltage level control signal received from the control circuit 41B.

The amplification module 20B includes the power amplifiers 21, 22, 23, and 24, the switches 31, 32, 33, and 34, and power supply voltage terminals 210, 220, 250, and 260.

The power supply voltage terminal 210 is an example of the first power supply voltage terminal. The power supply voltage terminal 210 is connected to the switches 31, 32, 33, and 34 and the DCDC converter 11B, and the power supply voltage Vcc1 is applied thereto. The power supply voltage terminal 220 is an example of the second power supply voltage terminal. The power supply voltage terminal 220 is connected to the switches 31 and 32 and the DCDC converter 12B, and the power supply voltage Vcc2 is applied thereto. The power supply voltage terminal 250 is connected to the switch 33 and the DCDC converter 13B, and the power supply voltage Vcc3 is applied thereto. The power supply voltage terminal 260 is connected to the switch 34 and the DCDC converter 14B, and the power supply voltage Vcc4 is applied thereto.

The power amplifier 21 is an example of the first amplification circuit, in which a signal input end is connected to the signal input terminal 110, a signal output end is connected to the antenna connection terminal 101, and a power supply input end is connected to power supply voltage terminals 210 and 220 through the switch 31.

The power amplifier 22 is an example of the second amplification circuit, in which a signal input end is connected to the signal input terminal 120, a signal output end is connected to the antenna connection terminal 102, and a power supply input end is connected to power supply voltage terminals 210 and 220 through the switch 32.

In the power amplifier 23, a signal input end is connected to the signal input terminal 130, a signal output end is connected to the antenna connection terminal 103, and a power supply input end is connected to the power supply voltage terminals 210 and 250 through the switch 33.

In the power amplifier 24, a signal input end is connected to the signal input terminal 140, a signal output end is connected to the antenna connection terminal 104, and a power supply input end is connected to the power supply voltage terminals 210 and 260 through the switch 34.

The switch 31 is an example of the first switch, and includes a common terminal 31a (first common terminal), a selection terminal 31b (first selection terminal), and a selection terminal 31c (second selection terminal), in which the common terminal 31a is connected to a power supply input end of the power amplifier 21, the selection terminal 31b is connected to the power supply voltage terminal 210, and the selection terminal 31c is connected to the power supply voltage terminal 220. According to this, the switch 31 selectively performs switching between a connection of the DCDC converter 11B and the power amplifier 21 and a connection of the DCDC converter 12B and the power amplifier 21. In addition, the switch 31 connects the DCDC converter 11B and the power amplifier 21 and disconnects the DCDC converter 12B and the power amplifier 21.

As a result, for example, the switch 31 can alternately select the DCDC converters 11B and 12B for each symbol based on the switching control signal output from the control circuit 41B and connect the selected DCDC converter to the power amplifier 21. As a result, the switch 31 can supply a power supply voltage V_{SPT} modulated by the SPT mode to the power amplifier 21. In addition, for example, the switch 31 can connect only the DCDC converter 11B to the power amplifier 21 without connecting the DCDC converter 12B to the power amplifier 21, based on the switching control signal output from the control circuit 41B. As a result, the switch 31 can supply a power supply voltage V_{APT} modulated by the APT mode to the power amplifier 21. In addition, at this time, the DCDC converter 12B can supply the power supply voltage VAPT modulated by the APT mode to the power amplifier 22.

The switch 32 is an example of the second switch, and includes a common terminal 32a (second common terminal), a selection terminal 32b (third selection terminal), and a selection terminal 32c (fourth selection terminal). The common terminal 32a is connected to a power supply input end of the power amplifier 22, the selection terminal 32b is connected to the power supply voltage terminal 220, and the selection terminal 32c is connected to the power supply voltage terminal 210. According to this, the switch 32 selectively performs switching between a connection of the DCDC converter 11B and the power amplifier 22 and a connection of the DCDC converter 12B and the power amplifier 22. In addition, the switch 32 connects the DCDC converter 12B and the power amplifier 22 and disconnects the DCDC converter 11B and the power amplifier 22.

As a result, for example, the switch 32 can alternately select the DCDC converters 11B and 12B for each symbol based on the switching control signal output from the control circuit 41B and connect the selected DCDC converter to the power amplifier 22. As a result, the switch 32 can supply the power supply voltage V_{SPT} modulated by the SPT mode to the power amplifier 22. In addition, for example, the switch 32 can connect only the DCDC converter 12B to the power amplifier 22 without connecting the DCDC converter 11B to the power amplifier 22, based on the switching control signal output from the control circuit 41B. As a result, the switch 32 can supply a power supply voltage V_{APT} modulated by the APT mode to the power amplifier 22. In addition, at this time, the DCDC converter 11B can supply the power supply voltage V_{APT} modulated by the APT mode to the power amplifier 21.

The switch 33 includes a common terminal 33a, a selection terminal 33b, and a selection terminal 33c. The common terminal 33a is connected to a power supply input end of the power amplifier 23, the selection terminal 33b is connected to the power supply voltage terminal 250, and the selection terminal 33c is connected to the power supply voltage terminal 210. According to this, the switch 33 selectively performs switching between a connection of the DCDC converter 11B and the power amplifier 23 and a connection of the DCDC converter 13B and the power amplifier 23. In addition, the switch 33 connects the DCDC converter 13B and the power amplifier 23 and disconnects the DCDC converter 11B and the power amplifier 23.

As a result, for example, the switch 33 can alternately select the DCDC converters 11B and 13B for each symbol based on the switching control signal output from the control circuit 41B and connect the selected DCDC converter to the power amplifier 23. As a result, the switch 33 can supply the power supply voltage VSPT modulated by the SPT mode to the power amplifier 23. In addition, for example, the switch 33 can connect only the DCDC converter 13B to the power amplifier 23 without connecting the DCDC converter 11B to the power amplifier 23, based on the switching control signal output from the control circuit 41B. As a result, the switch 33 can supply a power supply voltage V_{APT} modulated by the APT mode to the power amplifier 23. In addition, at this time, the DCDC converter 11B can supply the power supply voltage V_{APT} modulated by the APT mode to the power amplifier 21.

The switch 34 includes a common terminal 34a, a selection terminal 34b, and a selection terminal 34c. The common terminal 34a is connected to a power supply input end of the power amplifier 24, the selection terminal 34b is connected to the power supply voltage terminal 260, and the selection terminal 34c is connected to the power supply voltage terminal 210. According to this, the switch 34 selectively performs switching between a connection of the DCDC converter 11B and the power amplifier 24 and a connection of the DCDC converter 14B and the power amplifier 24. In addition, the switch 34 connects the DCDC converter 14B and the power amplifier 24 and disconnects the DCDC converter 11B and the power amplifier 24.

As a result, for example, the switch 34 can alternately select the DCDC converters 11B and 14B for each symbol based on the switching control signal output from the control circuit 41B and connect the selected DCDC converter to the power amplifier 24. As a result, the switch 34 can supply the power supply voltage V_{SPT} modulated by the SPT mode to the power amplifier 24. In addition, for example, the switch 34 can connect only the DCDC converter 14B to the power amplifier 24 without connecting the DCDC converter 11B to the power amplifier 24, based on the switching control signal output from the control circuit 41B. As a result, the switch 34 can supply a power supply voltage V_{APT} modulated by the APT mode to the power amplifier 24. In addition, at this time, the DCDC converter 11B can supply the power supply voltage V_{APT} modulated by the APT mode to the power amplifier 21

According to this, (1) each of the power amplifiers 21 to 24 can be caused to perform an amplification operation in the SPT mode by using the two DCDC converters, and (2) each of the power amplifiers 21 to 24 can be caused to perform an amplification operation in the APT mode by using the one DCDC converter, and two or more of the power amplifiers 21 to 24 can be caused to simultaneously perform an amplification operation in the APT mode. As a result, the four amplification circuits can perform a plurality of modes including the SPT mode and a mode in which the amplification operation is simultaneously performed, by using the four DCDC converters. Therefore, it is possible to provide a small-sized amplification system 1B performing SPT.

The configuration in which the power supply voltage is supplied from the two DCDC converters to each power amplifier is not limited to the above configuration. For example, the amplification system 1B may have a configuration in which the power supply voltage is supplied to the power amplifier 23 from the DCDC converters 13B and 14B, and the power supply voltage is supplied to the power amplifier 24 from the DCDC converters 13B and 14B.

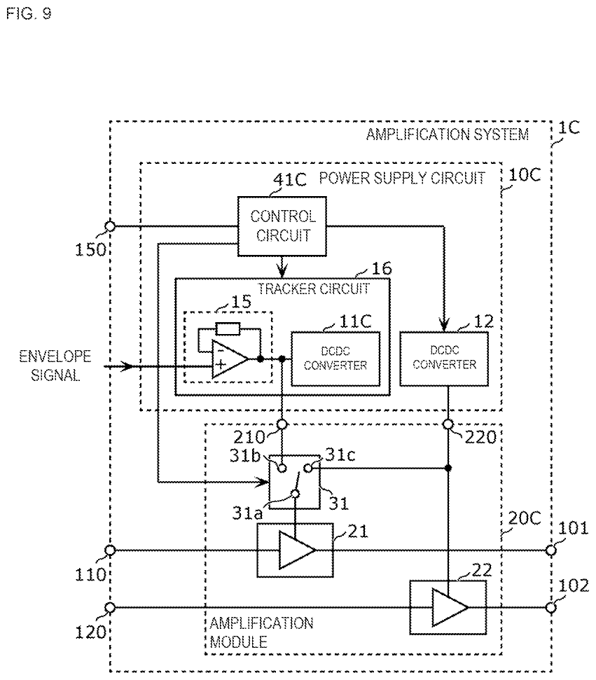

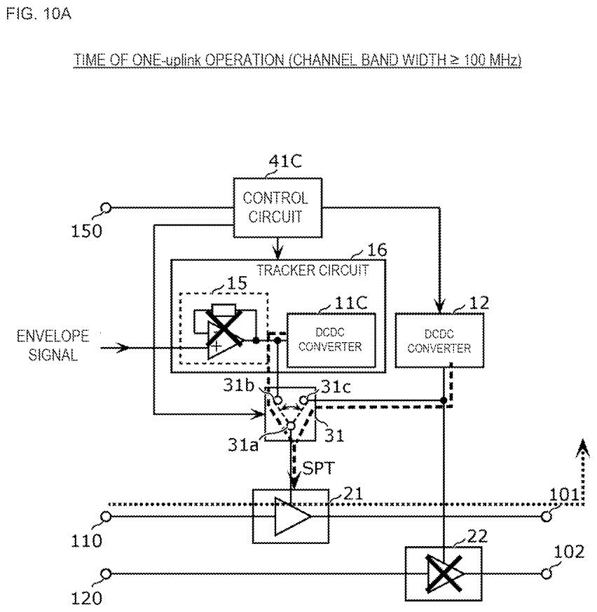

Next, an amplification system 1C according to an aspect of the present disclosure will be described with reference to FIG. 9.

FIG. 9 is a circuit configuration diagram of the amplification system 1C according to an aspect of the present disclosure. As illustrated in FIG. 9, the amplification system 1C according to an aspect of the present disclosure includes a power supply circuit 10C, an amplification module 20C, antenna connection terminals 101 and 102, signal input terminals 110 and 120, and a control signal terminal 150. The amplification system 1C according to an aspect of the present disclosure has a different configuration of the power supply circuit 10C as compared with the amplification system 1. The amplification system 1C will be described below mainly focusing on different configurations without describing the same configurations as the amplification system 1.

The power supply circuit 10C includes a DCDC converter 12, a tracker circuit 16, and a control circuit 41C.

The control circuit 41C can control the DCDC converter 12, the tracker circuit 16, and a switch 31 of the amplification module 20C. For example, in a case where the power supply voltage in the SPT mode is supplied to the amplification module 20C, the control circuit 41C can receive a digital control signal from the RFIC 3, provide a first voltage level control signal and a second voltage level control signal indicating the voltage level of the symbol to the tracker circuit 16 and the DCDC converter 12, respectively, and provide a switching control signal to the switch 31. In addition, for example, in a case where the power supply voltage in the APT mode is supplied to the amplification module 20C, the control circuit 41C can receive a control signal corresponding to the average power in one frame section from the RFIC 3, provide the first voltage level control signal and the second voltage level control signal corresponding to the average power to the tracker circuit 16 and the DCDC converter 12, respectively, and provide the switching control signal to the switch 31. In addition, for example, in a case where the power supply voltage of the analog ET mode is supplied to the amplification module 20C, the control circuit 41C can receive a control signal corresponding to an envelope value from the RFIC 3, provide the first voltage level control signal corresponding to the envelope value to the tracker circuit 16, and provide the switching control signal to the switch 31.

The tracker circuit 16 is an example of the first voltage output circuit and is configured to output a power supply voltage Vcc1 (first power supply voltage). The tracker circuit 16 includes a DCDC converter 11C and a linear amplifier circuit 15. The DCDC converter 11C includes, for example, one power inductor and outputs a DC voltage. The DCDC converter 11C can change the level of the DC voltage for each symbol corresponding to the DCDC converter 11C or for each average power, based on the first voltage level control signal received from the control circuit 41C. The linear amplifier circuit 15 receives an envelope signal indicating a power supply voltage waveform based on the envelope value from the RFIC 3 and linearly amplifies the envelope signal. The tracker circuit 16 is configured to switch the operation/non-operation of the linear amplifier circuit 15. The tracker circuit 16 outputs a power supply voltage Vcc1 (first power supply voltage) corresponding to the envelope value in a case where the linear amplifier circuit 15 operates, and outputs a DC power supply voltage Vcc1 (first power supply voltage) in a case where the linear amplifier circuit 15 does not operate.

The DCDC converter 12 is an example of a second voltage output circuit and is configured to output a power supply voltage Vcc2 (second power supply voltage). The DCDC converter 12 has, for example, one power inductor and outputs a DC power supply voltage Vcc2. The DCDC converter 12 can change the level of the power supply voltage Vcc2 for each symbol corresponding to the DCDC converter 12 or for each average power, based on the second voltage level control signal received from the control circuit 41C.

The amplification module 20C receives the supply of a variable power supply voltage in the SPT mode, the APT mode, the analog ET mode, or the like from the power supply circuit 10C, amplifies a radio frequency signal input from the RFIC 3, and outputs the amplified radio frequency signal from the antenna connection terminals 101 and 102. The amplification module 20C includes power amplifiers 21 and 22, the switch 31, and power supply voltage terminals 210 and 220.

The power supply voltage terminal 210 is an example of the first power supply voltage terminal. The power supply voltage terminal 210 is connected to the switch 31 and the tracker circuit 16, and the power supply voltage Vcc1 is applied thereto. The power supply voltage terminal 220 is an example of the second power supply voltage terminal. The power supply voltage terminal 220 is connected to the switch 31, the power amplifier 22, and the DCDC converter 12, and the power supply voltage Vcc2 is applied thereto.

The power amplifier 21 is an example of the first amplification circuit, in which a signal input end is connected to the signal input terminal 110, a signal output end is connected to the antenna connection terminal 101, and a power supply input end is connected to power supply voltage terminals 210 and 220 through the switch 31. The power amplifier 21 receives the supply of the power supply voltage from the power supply circuit 10C, amplifies, for example, a radio frequency signal having a band A, which is input from the signal input terminal 110, and outputs the amplified radio frequency signal to the antenna connection terminal 101.

The power amplifier 22 is an example of the second amplification circuit, in which a signal input end is connected to the signal input terminal 120, a signal output end is connected to the antenna connection terminal 102, and a power supply input end is connected to the power supply voltage terminal 220. The power amplifier 22 receives the supply of the power supply voltage from the power supply circuit 10C, amplifies, for example, a radio frequency signal having a band B, which is input from the signal input terminal 110, and outputs the amplified radio frequency signal to the antenna connection terminal 102.

The switch 31 is an example of the first switch, and includes a common terminal 31a (first common terminal), a selection terminal 31b (first selection terminal), and a selection terminal 31c (second selection terminal). The switch 31 selectively (exclusively) performs switching between a connection of the common terminal 31a and the selection terminal 31b and a connection of the common terminal 31a and the selection terminal 31c. The common terminal 31a is connected to the power supply input end of the power amplifier 21. The selection terminal 31b is connected to the tracker circuit 16 through the power supply voltage terminal 210. The selection terminal 31c is connected to the DCDC converter 12 through the power supply voltage terminal 220.

According to such a connection configuration, in the first mode, the switch 31 selectively performs switching between a connection of the tracker circuit 16 and the power amplifier 21 and a connection of the DCDC converter 12 and the power amplifier 21. In addition, in the second mode, the switch 31 connects the tracker circuit 16 and the power amplifier 21 and disconnects the DCDC converter 12 and the power amplifier 21. In addition, in the third mode, the switch 31 connects the tracker circuit 16 and the power amplifier 21 and disconnects the DCDC converter 12 and the power amplifier 21.

As a result, for example, the first mode is applied to the SPT mode, and the switch 31 can alternately select the DCDC converters 11C and 12 for each symbol based on the switching control signal output from the control circuit 41C and connect the selected DCDC converter to the power amplifier 21. As a result, the switch 31 can supply a power supply voltage V_{SPT} modulated by the SPT mode to the power amplifier 21.

In addition, for example, the second mode is applied to the APT mode, and the switch 31 can connect only or alternatively to the DCDC converter 11C to the power amplifier 21 without connecting the DCDC converter 12 to the power amplifier 21, based on the switching control signal output from the control circuit 41C. As a result, the switch 31 can supply a power supply voltage V_{APT} modulated by the APT mode to the power amplifier 21. In addition, at this time, the DCDC converter 12 can supply the power supply voltage V_{APT} modulated by the APT mode to the power amplifier 22.

In addition, for example, the third mode is applied to the analog ET mode, and the switch 31 can connect the tracker circuit 16 to the power amplifier 21 based on the switching control signal output from the control circuit 41C. As a result, the switch 31 can supply a power supply voltage V_{ET} modulated by the analog ET mode to the power amplifier 21.

Next, a circuit operation of the amplification system 1C will be described.

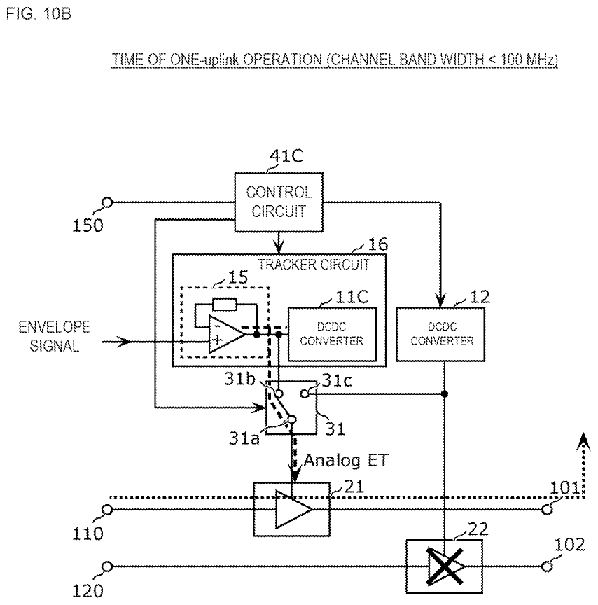

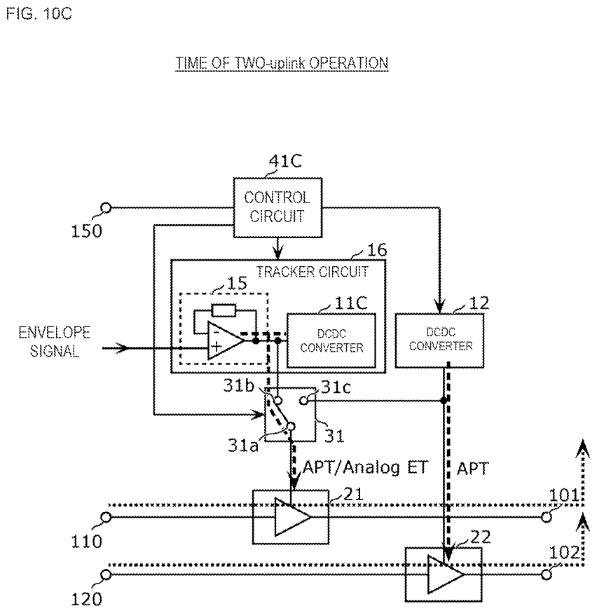

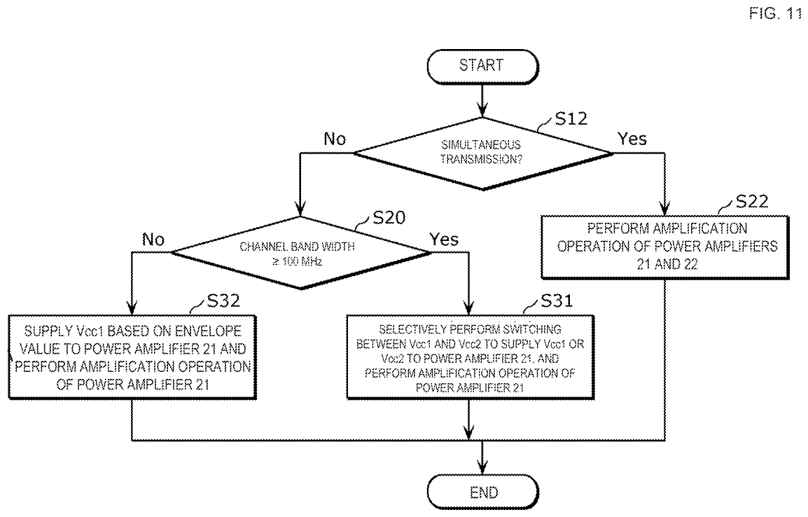

FIG. 10A is a diagram illustrating a circuit state of the amplification system 1C according to an aspect of the present disclosure at the time of a one-uplink operation (wide channel band width). FIG. 10A illustrates a circuit state in a case where the power amplifier 21 performs an amplification operation and the power amplifier 22 does not perform an amplification operation, and the first mode is performed. In this case, a radio frequency transmission signal having a band A with a channel band width of 100 MHz or more is output from the antenna connection terminal 101, and a radio frequency transmission signal of a band B is not output from the antenna connection terminal 102. At this time, the linear amplifier circuit 15 does not operate. The connection of the common terminal 31a and the selection terminal 31b and the connection of the common terminal 31a and the selection terminal 31c are selectively switched. The power supply voltages Vcc1 and Vcc2 are alternately supplied from the DCDC converters 11C and 12 to the power amplifier 21 for each symbol, and the power amplifier 21 performs an amplification operation in the SPT mode.

FIG. 10B is a diagram illustrating a circuit state of the amplification system 1C according to an aspect of the present disclosure at the time of a one-uplink operation (narrow channel band width). FIG. 10B illustrates a circuit state in a case where the power amplifier 21 performs an amplification operation and the power amplifier 22 does not perform an amplification operation, and the third mode is performed. In this case, a radio frequency transmission signal having a band A with a channel band width of less than 100 MHz is output from the antenna connection terminal 101, and a radio frequency transmission signal of a band B is not output from the antenna connection terminal 102. At this time, the linear amplifier circuit 15 operates, the common terminal 31a and the selection terminal 31b are connected, and the common terminal 31a and the selection terminal 31c are disconnected. The power supply voltage Vcc1 corresponding to the envelope value is supplied to the power amplifier 21, and the power amplifier 21 performs an amplification operation in the analog ET mode.

FIG. 10C is a diagram illustrating a circuit state of the amplification system 1C according to an aspect of the present disclosure at the time of a two-uplink operation. FIG. 10C illustrates a circuit state in a case where both the power amplifiers 21 and 22 perform the amplification operation, and the second mode is performed. In this case, for example, the radio frequency transmission signal having the band A is output from the antenna connection terminal 101, and the radio frequency transmission signal having the band B is output from the antenna connection terminal 102. At this time, the common terminal 31a and the selection terminal 31b are connected, and the common terminal 31a and the selection terminal 31c are disconnected. The power supply voltage Vcc1 corresponding to the average power is supplied to the power amplifier 21, the power supply voltage Vcc2 corresponding to the average power is supplied to the power amplifier 22, and the power amplifiers 21 and 22 perform the amplification operation in the APT mode.

In the case of the second mode, the power amplifier 21 may perform an amplification operation in the APT mode without operating the linear amplifier circuit 15, or the power amplifier 21 may perform the amplification operation in the analog ET mode with operating the linear amplifier circuit 15.

FIG. 11 is a flowchart illustrating a method of driving the amplification system 1C according to an aspect of the present disclosure. The mode in which the power supply voltage is supplied to the amplification system 1C include a first mode, a second mode, and a third mode.

In a case where only the first radio frequency signal having the band A is transmitted (the second radio frequency signal having the band B is not transmitted) (No in S12), and in a case where the channel band width of the first radio frequency signal is 100 MHz or more (Yes in S20), the power supply voltages Vcc1 and Vcc2 are selectively switched to supply the power supply voltage to the power amplifier 21, and the power amplifier 21 is caused to perform an amplification operation (S31: first mode). At this time, the power supply voltages Vcc1 and Vcc2 are not supplied to the power amplifier 22.

In addition, in a case where only the first radio frequency signal having the band A is transmitted (the second radio frequency signal having the band B is not transmitted) (No in S12), and in a case where the channel band width of the first radio frequency signal is less than 100 MHz (No in S20), the power supply voltage Vcc1 based on the envelope value is supplied to the power amplifier 21 to cause the power amplifier 21 to perform an amplification operation (S32: third mode).

In addition, in a case where the first radio frequency signal having the band A and the second radio frequency signal having the band B are simultaneously transmitted (Yes in S12), the power amplifier 21 and the power amplifier 22 are simultaneously caused to perform the amplification operation (S22: second mode).

That is, in a case where the power amplifier 21 is caused to perform the amplification operation, the power amplifier 22 is not caused to perform the amplification operation, and the channel band width of the radio frequency signal input to the power amplifier 21 is 100 MHz or more, the first mode is performed. In addition, in a case where the power amplifier 21 is caused to perform the amplification operation, the power amplifier 22 is not caused to perform the amplification operation, and the channel band width of the radio frequency signal input to the power amplifier 21 is less than 100 MHz, the third mode is performed. In addition, in a case where the power amplifiers 21 and 22 are simultaneously caused to perform the amplification operation, the second mode is performed.

A threshold value of the channel band width is not limited to 100 MHz and is freely set in accordance with the amplification system.

In the present aspect, the first mode is the SPT mode, the second mode is the APT mode, and the third mode is the analog ET mode. The second mode may include the analog ET mode.

As described above, the amplification system 1 according to the present aspect is configured to perform SPT and includes the DCDC converter 11 configured to output the power supply voltage Vcc1, the DCDC converter 12 configured to output the power supply voltage Vcc2, the power amplifiers 21 and 22, and the switch 31 configured to, in the first mode, selectively perform switching between the connection of the DCDC converter 11 and the power amplifier 21 and the connection of the DCDC converter 12 and the power amplifier 21, and, in the second mode, connect the DCDC converter 11 and the power amplifier 21, and connect the DCDC converter 12 and the power amplifier 22.

According to this, in the first mode, the power amplifier 21 can be caused to perform an amplification operation in the SPT mode by using the DCDC converters 11 and 12, and, in the second mode, the power amplifier 21 can be caused to perform an amplification operation by using the DCDC converter 11 and the power amplifier 22 can be caused to perform an amplification operation by using the DCDC converter 12. As a result, it is possible to perform a plurality of modes including the SPT mode and a mode in which the amplification operation is simultaneously performed on the two power amplifiers by using the two DCDC converters, while reducing the deterioration in the efficiency of the amplification system. Therefore, it is possible to provide a small-sized amplification system 1 performing SPT.

In addition, for example, in the amplification system 1, in a case where the power amplifier 21 performs an amplification operation and the power amplifier 22 does not perform an amplification operation, the first mode is performed, and, in a case where the power amplifiers 21 and 22 simultaneously perform the amplification operation, the second mode is performed.

According to this, in the first mode, only the power amplifier 21 performs the amplification operation by using the DCDC converters 11 and 12, and, in the second mode, the power amplifier 21 performs the amplification operation by using the DCDC converter 11 and the power amplifier 22 performs the amplification operation by using the DCDC converter 12. Therefore, it is possible to provide a small-sized amplification system 1 that is compatible with the independent transmission of a radio frequency signal and the simultaneous transmission of a radio frequency signal.

In addition, for example, in the amplification system 1, the first mode is the SPT mode, and the second mode is the APT mode.

According to this, it is possible to cause only the power amplifier 21 to perform an amplification operation in the SPT mode and to cause the power amplifiers 21 and 22 to perform an amplification operation in the APT mode. Therefore, it is possible to provide a small-sized amplification system 1 that is compatible with the independent transmission of a radio frequency signal in the SPT mode and the simultaneous transmission of a radio frequency signal in the APT mode while reducing the deterioration in the efficiency of the amplification system 1.

In addition, for example, in the amplification system 1C according to an aspect of the present disclosure, the tracker circuit 16 includes the linear amplifier circuit 15 that generates a voltage based on the envelope signal and the DCDC converter 11C that generates a DC voltage.

According to this, the tracker circuit 16 can output the variable power supply voltage based on the envelope signal by operating the linear amplifier circuit 15, and can output the DC power supply voltage by operating only the DCDC converter 11C.

In addition, for example, in the amplification system 1C, in the first mode, the linear amplifier circuit 15 does not operate. On the other hand, in the third mode, the linear amplifier circuit 15 operates, the switch 31 connects the tracker circuit 16 and the power amplifier 21, and does not connect the DCDC converter 12 and the power amplifier 21. In a case where the power amplifier 21 performs an amplification operation, the power amplifier 22 does not perform an amplification operation, and the channel band width of the radio frequency signal input to the power amplifier 21 is equal to or greater than a predetermined value, the first mode is performed. In addition, in a case where the power amplifier 21 performs an amplification operation, the power amplifier 22 does not perform an amplification operation, and the channel band width is less than the predetermined value, the third mode is performed. In addition, in a case where the power amplifiers 21 and 22 simultaneously perform the amplification operation, the second mode is performed.

According to this, in the first mode, the radio frequency signal having the wide channel band width is amplified only by the power amplifier 21 using the DCDC converters 11C and 12, and, in the second mode, the first radio frequency signal is amplified by the power amplifier 21 using the DCDC converter 11C and the second radio frequency signal is amplified by the power amplifier 22 using the DCDC converter 12. Further, in the third mode, the radio frequency signal having the narrow channel band width is amplified by only the power amplifier 21 using the linear amplifier circuit 15 and the DCDC converter 11C. Therefore, it is possible to provide a small-sized amplification system 1C that is compatible with the independent transmission of a radio frequency signal having the wide channel band width, the independent transmission of a radio frequency signal having the narrow channel band width, and the simultaneous transmission of a radio frequency signal.

In addition, for example, in the amplification system 1C, the first mode is the SPT mode, the second mode is the APT mode, and the third mode is the analog ET mode.

According to this, the radio frequency signal having a wide channel band width can be amplified in the SPT mode only by the power amplifier 21, and the power amplifiers 21 and 22 can be simultaneously caused to perform the amplification operation in the APT mode. Further, the amplification operation can be performed on the radio frequency signal having a narrow channel band width in the analog ET mode only by the power amplifier 21. Therefore, it is possible to provide a small-sized amplification system 1C that is compatible with the independent transmission of a radio frequency signal in the SPT mode, the independent transmission of a radio frequency signal in the analog ET mode, and the simultaneous transmission of a radio frequency signal in the APT mode.

In addition, for example, in the amplification systems 1, 1A, 1B, and 1C, the power amplifier 21 can amplify the radio frequency signal of the ultra-high band group, and the power amplifier 22 can amplify the radio frequency signals of the low band group and the middle-high band group.

According to this, the power amplifier 21 performing the SPT mode can be caused to perform the amplification operation on the radio frequency signal of the ultra-high band group that has a relatively wide channel band width, and the power amplifier 22 performing the APT mode can be caused to perform the amplification operation on the radio frequency signals of the low band group and the middle-high band group which have a relatively narrow channel band width. Therefore, it is possible to reduce the deterioration in the efficiency of the amplification system.

In addition, for example, the amplification system 1A according to an aspect of the present disclosure further includes the switch 32 configured to, in the fourth mode, selectively perform switching between the connection of the DCDC converter 11A and the power amplifier 22 and the connection of the DCDC converter 12A and the power amplifier 22, and, in the second mode, connect the DCDC converter 11A and the power amplifier 21 and connect the DCDC converter 12A and the power amplifier 22.

According to this, in the first mode, the power amplifiers 21 and 22 can be caused to perform the amplification operation in the SPT mode by using the DCDC converters 11A and 12A. In the second mode, the power amplifier 21 can be caused to perform the amplification operation by using the DCDC converter 11A and the power amplifier 22 can be caused to perform the amplification operation by using the DCDC converter 12A. In the fourth mode, the power amplifier 22 can be caused to perform the amplification operation in the SPT mode by using the DCDC converters 11A and 12A. As a result, the SPT mode can be performed for both the power amplifiers 21 and 22 by using the two DCDC converters. Therefore, it is possible to provide a small-sized amplification system 1A performing SPT for each of the plurality of power amplifiers.

In addition, for example, in the amplification system 1A, in a case where the power amplifier 22 performs an amplification operation and the power amplifier 21 does not perform an amplification operation, the fourth mode is performed.

According to this, in the fourth mode, only the power amplifier 22 performs the amplification operation by using the DCDC converter 11A and the DCDC converter 12A. Therefore, it is possible to provide a small-sized amplification system 1A that is compatible with the independent transmission of a radio frequency signal and the simultaneous transmission of a radio frequency signal.

In addition, for example, in the amplification system 1A, the fourth mode is the SPT mode.

According to this, it is possible to cause only the power amplifier 21 to perform an amplification operation in the SPT mode and to cause only the power amplifier 22 to perform an amplification operation in the SPT mode. Therefore, it is possible to provide a small-sized amplification system 1A that is compatible with the independent transmission of a radio frequency signal in the SPT mode and the simultaneous transmission of a radio frequency signal in the APT mode.

In addition, the amplification module 20 according to the present aspect is performing SPT and includes the power supply voltage terminal 210 to which the power supply voltage Vcc1 is applied and the power supply voltage terminal 220 to which the power supply voltage Vcc2 is applied, the power amplifier 21, the power amplifier 22 connected to the power supply voltage terminal 220, and the switch 31 that includes the common terminal 31a, the selection terminal 31b, and the selection terminal 31c, in which the common terminal 31a is connected to the power amplifier 21, the selection terminal 31b is connected to the power supply voltage terminal 210, and the selection terminal 31c is connected to the power supply voltage terminal 220.

According to this, (1) the power amplifier 21 can be caused to perform the amplification operation in the SPT mode by using the power supply voltages Vcc1 and Vcc2, and (2) the power amplifier 21 can be caused to perform the amplification operation by using the power supply voltage Vcc1, and the power amplifier 22 can be caused to perform the amplification operation by using the power supply voltage Vcc2. As a result, it is possible to perform a plurality of modes including the SPT mode for the two amplification circuits by supplying the power supply voltages from the two power supply voltage terminals, while reducing the deterioration in the efficiency of the amplification module 20. Therefore, it is possible to provide a small-sized amplification module 20 performing SPT.

In addition, for example, the amplification module 20 further includes the module laminate at which the power supply voltage terminals 210 and 220, the power amplifiers 21 and 22, and the switch 31 are disposed, and the power supply voltage terminals 210 and 220 are external connection terminals of the amplification module 20.

According to this, it is possible to provide a small-sized amplification module 20 in which circuit components are disposed at one module laminate.

In addition, for example, in the amplification module 20, in a case where the power amplifier 21 performs an amplification operation and the power amplifier 22 does not perform an amplification operation, the connection of the common terminal 31a and the selection terminal 31b and the connection of the common terminal 31a and the selection terminal 31c are selectively switched, and, in a case where the power amplifiers 21 and 22 simultaneously perform the amplification operation, the common terminal 31a and the selection terminal 31b are connected and the common terminal 31a and the selection terminal 31c are disconnected.

According to this, (1) the power amplifier 21 can be caused to perform the amplification operation in the SPT mode by using the power supply voltages Vcc1 and Vcc2, and (2) the power amplifier 21 can be caused to perform the amplification operation by using the power supply voltage Vcc1, and the power amplifier 22 can be caused to perform the amplification operation by using the power supply voltage Vcc2. As a result, it is possible to perform a plurality of modes including the SPT mode for the two amplification circuits by supplying the power supply voltages from the two power supply voltage terminals. Therefore, it is possible to provide a small-sized amplification module 20A performing SPT.

In addition, for example, the amplification module 20A according to an aspect of the present disclosure further includes the switch 32 that includes the common terminal 32a, the selection terminals 32b and 32c, in which the common terminal 32a is connected to the power amplifier 22, the selection terminal 32b is connected to the power supply voltage terminal 220, and the selection terminal 32c is connected to the power supply voltage terminal 210.

According to this, (1) the power amplifier 21 can be caused to perform the amplification operation in the SPT mode by using the power supply voltages Vcc1 and Vcc2, (2) the power amplifier 22 can be caused to perform the amplification operation in the SPT mode by using the power supply voltages Vcc1 and Vcc2, and (3) the power amplifier 21 can be caused to perform the amplification operation by using the power supply voltage Vcc1, and the power amplifier 22 can be caused to perform the amplification operation by using the power supply voltage Vcc2. As a result, it is possible to perform a plurality of modes including the SPT mode for the two amplification circuits by supplying the power supply voltages from the two power supply voltage terminals. Therefore, it is possible to provide a small-sized amplification module 20A performing SPT for each of the plurality of amplification circuits.

In addition, for example, (1) in a case where the power amplifier 22 performs an amplification operation and the power amplifier 21 does not perform an amplification operation, the connection of the common terminal 32a and the selection terminal 32b and the connection of the common terminal 32a and the selection terminal 32c are selectively switched, and, (2) in a case where the power amplifiers 21 and 22 simultaneously perform the amplification operation, the common terminal 32a and the selection terminal 32b are connected and the common terminal 32a and the selection terminal 32c are disconnected.

According to this, only the power amplifier 22 performs the amplification operation by using the power supply voltages Vcc1 and Vcc2. Therefore, it is possible to provide a small-sized amplification module 20A that is compatible with the independent transmission of a radio frequency signal and the simultaneous transmission of a radio frequency signal.

In addition, for example, the method of driving the amplification system 1 according to the present aspect is performing SPT. The mode of supplying the power supply voltage to the amplification system 1 includes the first mode and the second mode. In the first mode, the power supply voltage Vcc1 and the power supply voltage Vcc2 are selectively switched to cause the power amplifier 21 to perform an amplification operation and not to cause the power amplifier 22 to perform an amplification operation. In the second mode, the power amplifier 21 and the power amplifier 22 are simultaneously caused to perform the amplification operation.

According to this, it is possible to perform the plurality of modes including the SPT mode for the two power amplifiers 21 and 22 by using the two power supply voltages Vcc1 and Vcc2, while reducing the deterioration in the efficiency of the amplification system 1. Therefore, it is possible to provide a small-sized amplification system 1 performing SPT.

In addition, for example, in the method of driving the amplification system 1, the first mode is the SPT mode, and the second mode is the APT mode.

According to this, it is possible to cause only the power amplifier 21 to perform an amplification operation in the SPT mode and to cause the power amplifiers 21 and 22 to perform an amplification operation in the APT mode. Therefore, it is possible to provide a small-sized amplification system 1 that is compatible with the independent transmission of a radio frequency signal in the SPT mode and the simultaneous transmission of a radio frequency signal in the APT mode.

In addition, for example, in the method of driving the amplification system 1C according to an aspect of the present disclosure, in a case where the power amplifier 21 is caused to perform the amplification operation, the power amplifier 22 is not caused to perform the amplification operation, and the channel band width of the radio frequency signal input to the power amplifier 21 is equal to or more than a predetermined value, the first mode is performed. In a case where the power amplifier 21 is caused to perform the amplification operation, the power amplifier 22 is not caused to perform the amplification operation, and the channel band width of the radio frequency signal input to the power amplifier 21 is less than the predetermined value, the third mode in which the power supply voltage Vcc1 based on the envelope value of the radio frequency signal is supplied to the power amplifier 21 is performed. In a case where the power amplifier 21 and the power amplifier 22 are simultaneously caused to perform the amplification operation, the second mode is performed.

According to this, in the first mode, the radio frequency signal having the wide channel band width is amplified by only the power amplifier 21 using the power supply voltages Vcc1 and Vcc2, and, in the second mode, the first radio frequency signal is amplified by the power amplifier 21 using the power supply voltage Vcc1 and the second radio frequency signal is amplified by the power amplifier 22 using the power supply voltage Vcc2. Further, in the third mode, the radio frequency signal having the narrow channel band width is amplified by only the power amplifier 21 by using the power supply voltage Vcc1 based on the envelope value. Therefore, it is possible to provide a small-sized amplification system 1C that is compatible with the independent transmission of a radio frequency signal having the wide channel band width, the independent transmission of a radio frequency signal having the narrow channel band width, and the simultaneous transmission of a radio frequency signal.

In addition, for example, the first mode is the SPT mode, the second mode is the APT mode, and the third mode is the analog ET mode.

According to this, the radio frequency signal having a wide channel band width can be amplified in the SPT mode only by the power amplifier 21, and the power amplifiers 21 and 22 can be simultaneously caused to perform the amplification operation in the APT mode. Further, the amplification operation can be performed on the radio frequency signal having a narrow channel band width in the analog ET mode only by the power amplifier 21. Therefore, it is possible to provide a small-sized amplification system 1C that is compatible with the independent transmission of a radio frequency signal in the SPT mode, the independent transmission of a radio frequency signal in the analog ET mode, and the simultaneous transmission of a radio frequency signal in the APT mode.

Hitherto, the amplification system, the amplification module, and the method of driving the amplification system according to the present disclosure have been described based on the aspects and the examples, but the amplification system, the amplification module, and the method of driving the amplification system according to the present disclosure are not limited to the above-described aspects and examples. The present disclosure also includes another aspect realized by combining any constituents in the aspects described above, a modification obtained by making various modifications that can be conceived of by those skilled in the art with respect to the aspects described above within a range that does not deviate from the gist of the present disclosure, or various devices incorporating the above amplification system and amplification module.

For example, in circuit configurations of the amplification system and the amplification module according to the above-described aspects and the examples, another circuit element, another wiring, or the like may be inserted into the path for connecting the circuit elements and the signal paths disclosed in the drawings.

The following describes the features of the amplification system, the amplification module, and the method of driving the amplification system described above based on each aspect.

In general, the description of the aspects disclosed should be considered as being illustrative in all respects and not being restrictive. The scope of the present disclosure is shown by the claims rather than by the above description, and is intended to include meanings equivalent to the claims and all changes in the scope. While preferred aspects of the invention have been described above, it is to be understood that variations and modifications will be apparent to those skilled in the art without departing from the scope and spirit of the invention.

### DESCRIPTION OF REFERENCE SYMBOLS

1, 1A, 1B, 1C AMPLIFICATION SYSTEM
2a, 2b ANTENNA
3 RFIC
4, 4A COMMUNICATION DEVICE
10, 10A, 10B, 10C POWER SUPPLY CIRCUIT
11, 11A, 11B, 11C, 12, 12A, 12B, 13B, 14B DCDC CONVERTER
15 LINEAR AMPLIFIER CIRCUIT
16 TRACKER CIRCUIT
20, 20A, 20B, 20C AMPLIFICATION MODULE
21, 22, 23, 24 POWER AMPLIFIER
31, 32, 33, 34 SWITCH
31a, 32a, 33a, 34a COMMON TERMINAL
31b, 31c, 32b, 32c, 33b, 33c, 34b, 34c SELECTION TERMINAL
41, 41A, 41B, 41C CONTROL CIRCUIT
101, 102, 103, 104 ANTENNA CONNECTION TERMINAL
110, 120, 130, 140 SIGNAL INPUT TERMINAL
150 CONTROL SIGNAL TERMINAL
210, 220, 250, 260 POWER SUPPLY VOLTAGE TERMINAL

1. An amplification system for performing symbol power tracking (SPT), the amplification system comprising:
a first voltage output circuit configured to output a first power supply voltage;
a second voltage output circuit configured to output a second power supply voltage;
a first amplification circuit;
a second amplification circuit; and
a first switch configured to, in a first mode, selectively perform switching between a connection of the first voltage output circuit and the first amplification circuit and a connection of the second voltage output circuit and the first amplification circuit and, in a second mode, connect the first voltage output circuit and the first amplification circuit and connect the second voltage output circuit and the second amplification circuit.

2. The amplification system according to claim 1, wherein:
when the first amplification circuit performs an amplification operation and the second amplification circuit does not perform an amplification operation, the first mode is performed, and
when the first amplification circuit and the second amplification circuit simultaneously perform an amplification operation, the second mode is performed.

3. The amplification system according to claim 1, wherein the first mode is an SPT mode, and the second mode is an average power tracking (APT) mode.

4. The amplification system according to claim 1, wherein the first voltage output circuit includes a linear amplifier circuit that generates a voltage based on an envelope signal, and a DC/DC converter that generates a DC voltage.

5. The amplification system according to claim 4, wherein:
in the first mode, the linear amplifier circuit does not operate,
in a third mode, the linear amplifier circuit operates, and the first switch connects the first voltage output circuit and the first amplification circuit and does not connect the second voltage output circuit and the first amplification circuit,
when the first amplification circuit performs an amplification operation, the second amplification circuit does not perform an amplification operation, and a channel band width of a radio frequency signal input to the first amplification circuit is equal to or more than a predetermined value, the first mode is performed,
when the first amplification circuit performs an amplification operation, the second amplification circuit does not perform an amplification operation, and the channel band width is less than the predetermined value, the third mode is performed, and
when the first amplification circuit and the second amplification circuit simultaneously perform an amplification operation, the second mode is performed.

6. The amplification system according to claim 5, wherein the first mode is an SPT mode, the second mode is an APT mode, and the third mode is an analog envelope tracking (analog ET) mode.

7. The amplification system according to claim 1, wherein:
the first amplification circuit is configured to amplify a radio frequency signal of an ultra-high band group, and
the second amplification circuit is configured to amplify a radio frequency signal of a low band group and a radio frequency signal of a middle-high band group.

8. The amplification system according to claim 1, further comprising:
a second switch configured to, in a fourth mode, selectively perform switching between a connection of the first voltage output circuit and the second amplification circuit and a connection of the second voltage output circuit and the second amplification circuit and, in the second mode, connect the first voltage output circuit and the first amplification circuit and connect the second voltage output circuit and the second amplification circuit.

9. The amplification system according to claim 8, wherein the fourth mode is performed when the second amplification circuit performs an amplification operation and the first amplification circuit does not perform an amplification operation.

10. The amplification system according to claim 8, wherein the fourth mode is an SPT mode.

11. An amplification module for performing SPT, the amplification module comprising:
a first power supply voltage terminal to which a first power supply voltage is applied and a second power supply voltage terminal to which a second power supply voltage is applied;
a first amplification circuit;
a second amplification circuit connected to the second power supply voltage terminal; and
a first switch that includes a first common terminal, a first selection terminal, and a second selection terminal,
wherein the first common terminal is connected to the first amplification circuit, the first selection terminal is connected to the first power supply voltage terminal, and the second selection terminal is connected to the second power supply voltage terminal.

12. The amplification module according to claim 11, further comprising:
a module laminate at which the first power supply voltage terminal, the second power supply voltage terminal, the first amplification circuit, the second amplification circuit, and the first switch are disposed,
wherein the first power supply voltage terminal and the second power supply voltage terminal are external connection terminals of the amplification module.

13. The amplification module according to claim 11, wherein:
when the first amplification circuit performs an amplification operation and the second amplification circuit does not perform an amplification operation, a connection of the first common terminal and the first selection terminal and a connection of the first common terminal and the second selection terminal are selectively switched, and
when the first amplification circuit and the second amplification circuit simultaneously perform an amplification operation, the first common terminal and the first selection terminal are connected and the first common terminal and the second selection terminal are disconnected.

14. The amplification module according to claim 11, further comprising:
a second switch that includes a second common terminal, a third selection terminal, and a fourth selection terminal,
wherein the second common terminal is connected to the second amplification circuit, the third selection terminal is connected to the second power supply voltage terminal, and the fourth selection terminal is connected to the first power supply voltage terminal.

15. The amplification module according to claim 14, wherein:
when the second amplification circuit performs an amplification operation and the first amplification circuit does not perform an amplification operation, a connection of the second common terminal and the third selection terminal and a connection of the second common terminal and the fourth selection terminal are selectively switched, and
when the first amplification circuit and the second amplification circuit simultaneously perform an amplification operation, the second common terminal and the third selection terminal are connected and the second common terminal and the fourth selection terminal are disconnected.

16. A method of driving an amplification system configured to perform SPT, the method comprising:
supplying a power supply voltage to the amplification system in a mode including a first mode and a second mode,
wherein, in the first mode, a first power supply voltage and a second power supply voltage are selectively switched to initiate a first amplification circuit to perform an amplification operation and configure a second amplification circuit not to perform an amplification operation, and
wherein, in the second mode, the first amplification circuit and the second amplification circuit are simultaneously configured to perform an amplification operation.

17. The method of driving an amplification system according to claim 16, wherein the first mode is an SPT mode, and the second mode is an APT mode.

18. The method of driving an amplification system according to claim 16, wherein:
when the first amplification circuit performs an amplification operation, the second amplification circuit is not configured to perform an amplification operation, and a channel band width of a radio frequency signal input to the first amplification circuit is equal to or more than a predetermined value, the first mode is performed,
when the first amplification circuit performs an amplification operation, the second amplification circuit is not configured to perform an amplification operation, and the channel band width is less than the predetermined value, a third mode in which the first power supply voltage based on an envelope value of a radio frequency signal is supplied to the first amplification circuit is performed, and
when the first amplification circuit and the second amplification circuit simultaneously perform an amplification operation, the second mode is performed.

19. The method of driving an amplification system according to claim 18, wherein the first mode is an SPT mode, the second mode is an APT mode, and the third mode is an analog ET mode.
